(19) United States
(12) Patent Application Publication
(10) Pub. No.: US 2025/0081825 A1
(43) Pub. Date: Mar. 6, 2025

(54) DISPLAY PANEL AND DISPLAY DEVICE

(71) Applicants: Yunnan Invensight Optoelectronics Technology Co., Ltd., Kunming, Yunnan (CN); BOE TECHNOLOGY GROUP CO., LTD., Beijing (CN)

(72) Inventors: Zongshun Yang, Beijing (CN); Xiaobin Shen, Beijing (CN)

(73) Assignees: Yunnan Invensight Optoelectronics Technology Co., Ltd., Kunming, Yunnan (CN); BOE TECHNOLOGY GROUP CO., LTD., Beijing (CN)

(21) Appl. No.: 18/579,581

(22) PCT Filed: Mar. 10, 2023
(86) PCT No.: PCT/CN2023/080720

§ 371 Date: Jan. 16, 2024

(51) Int. Cl. H10K 59/80; H10K 59/122

(52) U.S. Cl. CPC H10K 59/879; H10K 59/122

(57) ABSTRACT

A display panel and a display device are disclosed. The display panel includes a base substrate and sub-pixels thereon. The base substrate includes first and second display regions. The sub-pixels include first and second sub-pixels. The first sub-pixels are in the first display region. The second sub-pixels are in the second display region. The display panel includes a lens layer at a side of the sub-pixels facing away from the base substrate. The lens layer includes first and second lenses. An orthographic projection of the first lens onto the base substrate at least partially overlaps with an orthographic projection of corresponding first pixel aperture onto the base substrate. An orthographic projection of the second lens onto the base substrate at least partially overlaps with an orthographic projection of corresponding second pixel aperture onto the base substrate. The first lens's light gathering ability is less than that of the second lens.

### TECHNICAL FIELD

The present disclosure relates to the field of display technologies, in particular to a display panel and a display device.

### BACKGROUND

With the continuous development of display technologies, micro organic light-emitting diode (Micro OLED) display products appear more and more in the public field of view. Such a micro OLED display product can achieve a higher pixel density and can be widely applied to various near-eye displays.

### SUMMARY

An objective of the present disclosure is to provide a display panel and a display device.

In order to achieve the foregoing objective, the present disclosure provides the following technical solutions.

A first aspect of the present disclosure provides display panel, which includes a base substrate and a plurality of sub-pixels on the base substrate; wherein the base substrate includes a first display region and a second display region; the plurality of sub-pixels include a plurality of first sub-pixels and a plurality of second sub-pixels; the first sub-pixels are in the first display region; the second sub-pixels are in the second display region; among sub-pixels of an identical color, a first pixel aperture of the first sub-pixels is greater than a second pixel aperture of the second sub-pixels; the display panel further includes:
a lens layer at a side of the plurality of sub-pixels facing away from the base substrate; wherein the lens layer includes a plurality of first lenses and a plurality of second lenses; an orthographic projection of the first lens onto the base substrate at least partially overlaps with an orthographic projection of the corresponding first pixel aperture onto the base substrate; an orthographic projection of the second lens onto the base substrate at least partially overlaps with an orthographic projection of the corresponding second pixel aperture onto the base substrate;
a light gathering ability of the first lens is less than a light gathering ability of the second lens.

Optionally, an arch height of the first lens is less than an arch height of the second lens.

Optionally, the arch height h1 of the first lens satisfies: 1.2 μm≤h1≤2.3 μm.

Optionally, a distance d1 between orthographic projections of the adjacent first lenses onto the base substrate and a distance d2 between orthographic projections of the adjacent second lenses onto the base substrate satisfy: d1>d2.

Optionally, d1 satisfies: 0.3 μm≤d1≤1 μm.

Optionally, the orthographic projection of the first lens onto the base substrate is surrounded by the orthographic projection of the corresponding first pixel aperture onto the base substrate.

Optionally, the orthographic projection of the second lens onto the base substrate surrounds at least part of a boundary of the orthographic projection of the corresponding second pixel aperture onto the base substrate.

Optionally, the orthographic projection of the second lens onto the base substrate surrounds the orthographic projection of the corresponding second pixel aperture onto the base substrate.

Optionally, a material of the first lens is different from a material of the second lens and a refractive index of the material of the first lens is less than a refractive index of the material of the second lens.

Optionally, the second display region includes a sub-display region and the sub-display region is adjacent to the first display region; in the sub-display region, the light gathering ability of the second lens corresponding to the second sub-pixel is gradually reduced in a direction close to the first display region.

Optionally, in the sub-display region, an arch height of the second lens corresponding to the second sub-pixel is gradually reduced in the direction close to the first display region.

Optionally, a distance between orthographic projections of the adjacent second lenses onto the base substrate is d2; in the sub-display region, d2 gradually increases in the direction close to the first display region.

Optionally, the plurality of first sub-pixels include a plurality of first blue sub-pixels, a plurality of first green sub-pixels and a plurality of first red sub-pixels;
the light gathering ability of the first lens corresponding to the first blue sub-pixel is greater than the light gathering ability of the first lens corresponding to the first green sub-pixel; and/or,
the light gathering ability of the first lens corresponding to the first blue sub-pixel is greater than the light gathering ability of the first lens corresponding to the first red sub-pixel.

Optionally, the plurality of second sub-pixels include a plurality of second blue sub-pixels, a plurality of second green sub-pixels and a plurality of second red sub-pixels;
the light gathering ability of the second lens corresponding to the second blue sub-pixel is greater than the light gathering ability of the second lens corresponding to the second green sub-pixel; and/or,
the light gathering ability of the second lens corresponding to the second blue sub-pixel is greater than the light gathering ability of the second lens corresponding to the second red sub-pixel.

Optionally, the plurality of first sub-pixels include a plurality of first blue sub-pixels, a plurality of first green sub-pixels and a plurality of first red sub-pixels;
the light gathering ability of the first lens corresponding to the first red sub-pixel is greater than the light gathering ability of the first lens corresponding to the first green sub-pixel; and/or,
the light gathering ability of the first lens corresponding to the first red sub-pixel is greater than the light gathering ability of the first lens corresponding to the first blue sub-pixel.

Optionally, the plurality of second sub-pixels include a plurality of second blue sub-pixels, a plurality of second green sub-pixels and a plurality of second red sub-pixels;
the light gathering ability of the second lens corresponding to the second red sub-pixel is greater than the light gathering ability of the second lens corresponding to the second green sub-pixel; and/or,
the light gathering ability of the second lens corresponding to the second red sub-pixel is greater than the light gathering ability of the second lens corresponding to the second blue sub-pixel.

Optionally, each of the first sub-pixel and the second sub-pixel includes: a sub-pixel driving circuit and a light-emitting element, wherein the light-emitting element includes an anode pattern, a light-emitting functional layer, a cathode layer and a color film layer which are sequentially stacked in a direction away from the base substrate, and the anode pattern is coupled to the sub-pixel driving circuit;
the display panel further includes: a pixel defining layer, wherein at least part of the pixel defining layer is located between the anode pattern and the light-emitting functional layer; the pixel defining layer includes a plurality of openings and the plurality of openings are used for defining the first pixel aperture and the second pixel aperture.

Based on the technical solution of the foregoing display panel, a second aspect of the present disclosure provides a display device, including the foregoing display panel.

### BRIEF DESCRIPTION OF THE DRAWINGS

The drawings described herein are used to provide a further understanding of the present disclosure and constitute a part of the disclosure. The exemplary embodiments of the disclosure and the descriptions thereof are used to explain the disclosure, and do not constitute improper limitations to the disclosure. In the drawings:

FIG. 1 is a schematic diagram of splicing exposure of a display panel according to an embodiment of the present disclosure;

FIG. 2 is a schematic diagram of a bright line appearing on a display panel in related art;

FIG. 3 is a schematic diagram of different sizes of pixel apertures of a first display region and a second display region of a display panel according to an embodiment of the present disclosure;

FIG. 4 is a schematic diagram of adjusting a lens size of a display panel according to an embodiment of the present disclosure;

FIG. 5 is a schematic diagram of a first cross-section of a first display region of a display panel according to an embodiment of the present disclosure;

FIG. 6 is a schematic diagram of a first cross-section of a second display region of a display panel according to an embodiment of the present disclosure;

FIG. 7 is a schematic diagram of a second cross-section of a second display region of a display panel according to an embodiment of the present disclosure; and

FIG. 8 is a schematic diagram of a third cross-section of a second display region of a display panel according to an embodiment of the present disclosure.

### DETAILED DESCRIPTION

In order to further describe the display panel and the display device provided by the embodiments of the present disclosure, a detailed description is provide hereinafter in conjunction with the accompanying drawings.

The manufacturing of the micro OLED display product is limited to the effective exposure area of the fine exposure machine, which has a maximum exposure area of 1.3 inch. The micro OLED display product with the size exceeding 1.3 inch needs to complete exposure in a splicing mode when the micro OLED display product with the size exceeding 1.3 inch is subjected to a photoetching process.

In the splicing exposure process, in order to ensure that seamless splicing can be achieved for multiple exposures, repeated exposure needs to be performed in a splicing region (of a width is between 10 μm and 15 um) with multiple exposures. As shown in FIG. 1, a splicing region formed between the first exposure region and the second exposure region is repeatedly exposed.

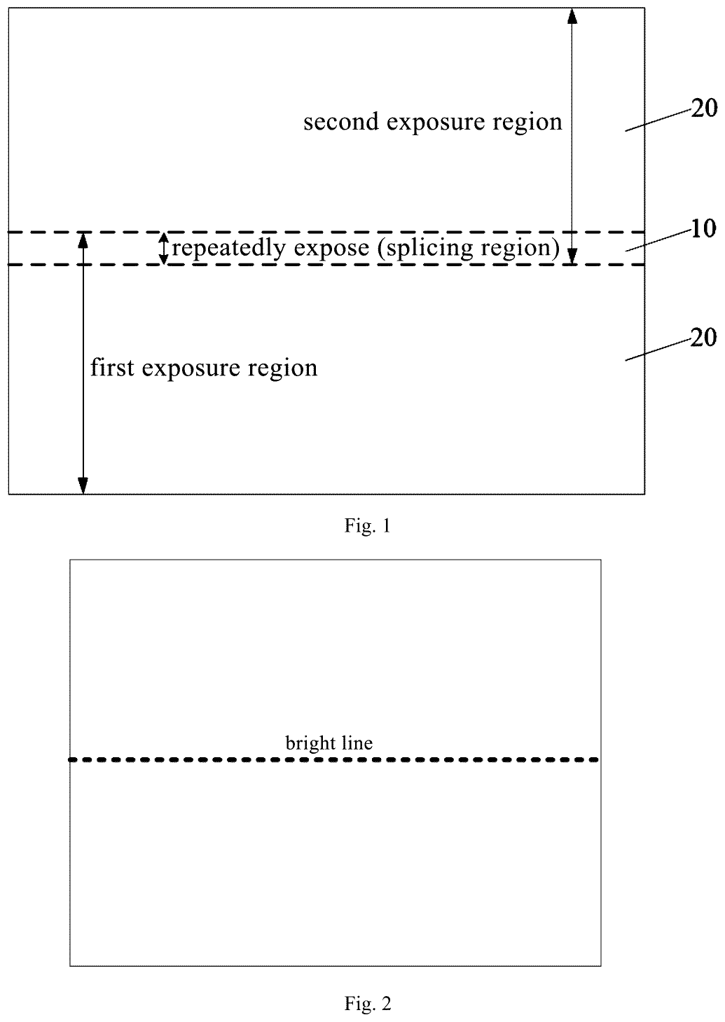

When the splicing exposure process is used to produce a pixel defining layer in a display product, an aperture in the pixel defining layer located in a splicing area is larger than an aperture in the pixel defining layer located in a non-splicing area, resulting in a higher brightness in the splicing area than in the non-splicing area, which appears as a bright line on some fine display products, as shown in FIG. 2.

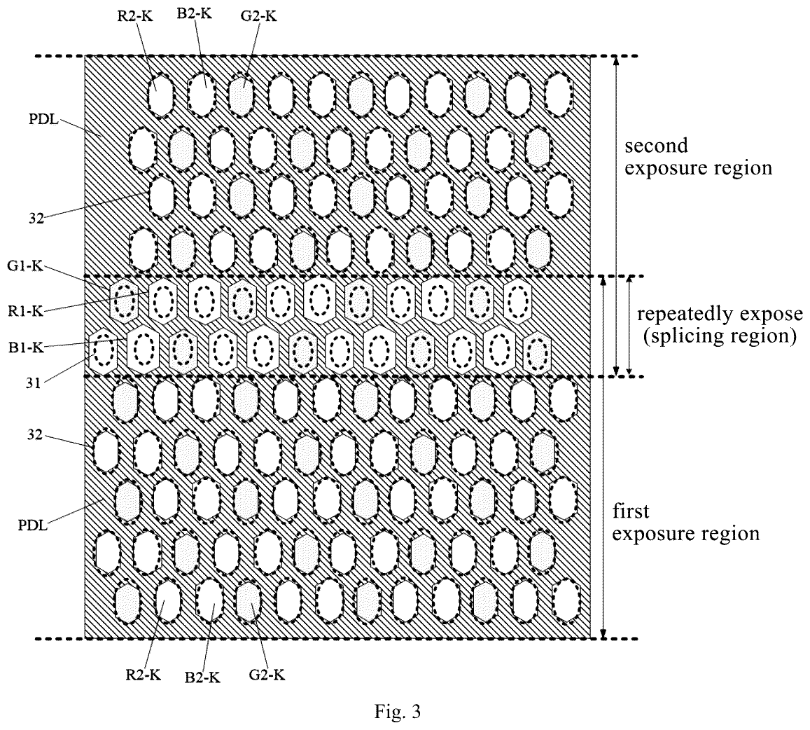

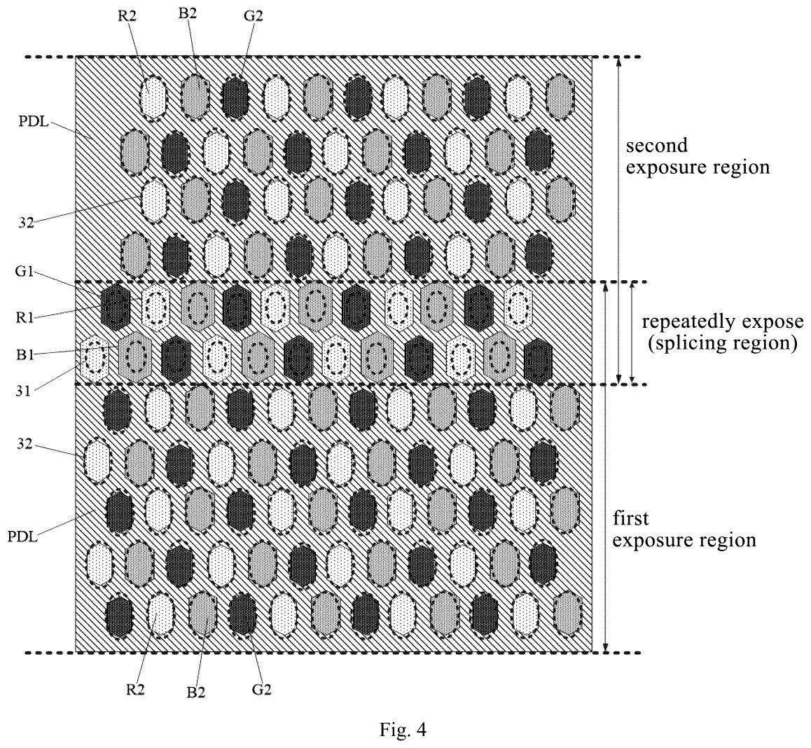

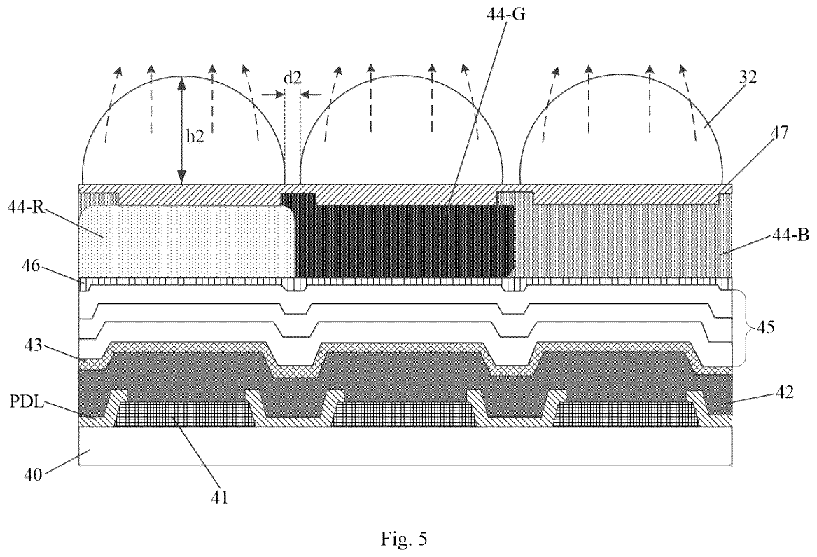

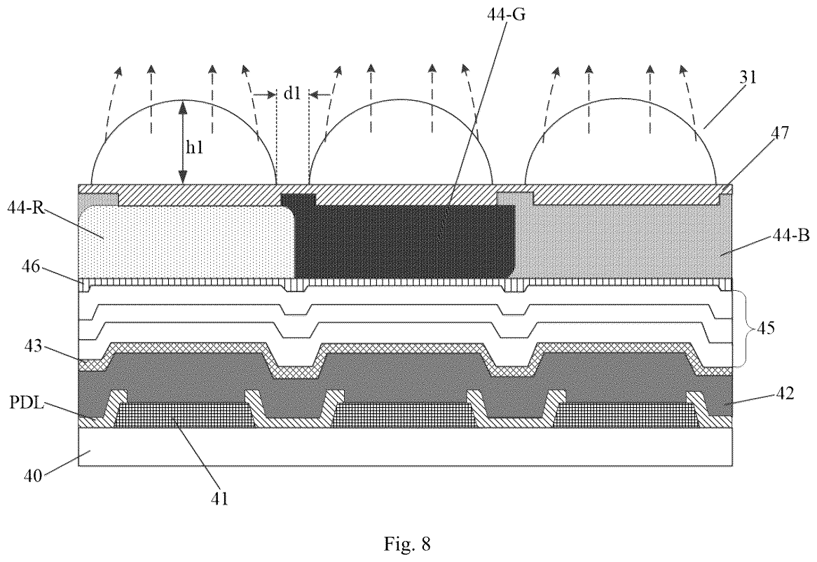

Referring to FIG. 1, FIG. 3, FIG. 4, FIG. 5, and FIG. 8, an embodiment of the present disclosure provides a display panel, including: a base substrate 40 and a plurality of sub-pixels on the base substrate 40. The base substrate 40 includes a first display region 10 and a second display region 20. The plurality of sub-pixels include a plurality of first sub-pixels (for example, a plurality of first blue sub-pixels B1, a plurality of first green sub-pixels G1, a plurality of first red sub-pixels R1) and second sub-pixels (for example, a plurality of second blue sub-pixels B2, a plurality of second green sub-pixels G2, and a plurality of second red sub-pixels R2). The first sub-pixels are located in the first display region 10. The second sub-pixels are located in the second display region 20. Among sub-pixels of the same color, a first pixel aperture of the first sub-pixels is greater than a second pixel aperture of the second sub-pixels. The display panel further includes:

a lens layer, located on a side of the plurality of sub-pixels facing away from the base substrate 40. The lens layer includes a plurality of first lenses 31 and a plurality of second lenses 32. An orthographic projection of the first lens 31 onto the base substrate 40 at least partially overlaps with an orthographic projection of the corresponding first pixel aperture onto the base substrate 40. An orthographic projection of the second lens 32 onto the base substrate 40 at least partially overlaps with an orthographic projection of the corresponding second pixel aperture onto the base substrate 40. A light gathering ability of the first lens 31 is less than a light gathering ability of the second lens 32.

It is to be noted that, in FIG. 3 and FIG. 4, the plurality of first lenses 31 and second lenses 32 are represented by dotted circles and the dotted circles show the boundary of the orthographic projection of the lens onto the base substrate. FIG. 3 shows an overlapping condition of pixel apertures formed by a pixel defining layer PDL and the first lens 31 and the second lens 32. Exemplarily, a center of the lens is aligned with a center of the pixel aperture. In FIG. 4, a color film layer is added relative to FIG. 3 and the color film layer overlaps with the corresponding pixel aperture.

Exemplarily, when the pixel defining layer PDL in the display panel is manufactured, a portion of the pixel defining layer PDL located in the first display region 10 undergoes two exposures, and a portion of the pixel defining layer PDL located in the second display region 20 undergoes one exposure. The portion of the pixel defining layer PDL located in the first display region 10 is used to define a size of the first pixel aperture, and the portion of the pixel defining layer PDL located in the second display region 20 is used to define a size of the second pixel aperture. Since the portion of the pixel defining layer PDL located in the first display region 10 undergoes two exposures, in the sub-pixels of the same color, the first pixel aperture is greater than the second pixel aperture.

Exemplarily, the plurality of first sub-pixels are distributed in an array in the first display region 10; and the plurality of second sub-pixels are distributed in an array in the second display region 20.

Exemplarily, the plurality of first sub-pixels include a plurality of first blue sub-pixels B1, a plurality of first green sub-pixels G1, and a plurality of first red sub-pixels R1. The plurality of first sub-pixels are divided into a plurality of rows of first sub-pixels, and each row of first sub-pixels includes first red sub-pixels R1, first green sub-pixels G1 and first blue sub-pixels B1 arranged in an alternating cycle.

Exemplarily, the plurality of second sub-pixels include a plurality of second blue sub-pixels B2, a plurality of second green sub-pixels G2, and a plurality of second red sub-pixels R2; the plurality of second sub-pixels are divided into a plurality of rows of second sub-pixels, and each row of second sub-pixels includes second red sub-pixels R2, second green sub-pixels G2, and second blue sub-pixels B2 arranged in an alternating cycle.

Exemplarily, a first pixel aperture R1-K of the first red sub-pixel R1 is greater than a second pixel aperture R2-K of the second red sub-pixel R2. A first pixel aperture G1-K of the first green sub-pixel G1 is greater than a second pixel aperture G2-K of the second green sub-pixel G2. A first pixel aperture B1-K of the first blue sub-pixel B1 is greater than a second pixel aperture B2-K of the second blue sub-pixel B2.

Exemplarily, the second display region 20 includes at least one row of second sub-pixels; and/or, the second display region 20 includes at least one column of second sub-pixels.

Exemplarily, the lens layer is located at a light emitting side of the plurality of sub-pixels. The lens layer includes a plurality of first lenses 31 and a plurality of second lenses 32. The plurality of first lenses 31 are distributed in the first display region 10 in an array and the plurality of second lenses 32 are distributed in the second display region 20 in an array.

Exemplarily, an overlapping area of the orthographic projection of the first lens 31 onto the base substrate 40 and the orthographic projection of the corresponding first pixel aperture onto the base substrate 40 is greater than or equal to 80% S, where S is an area of the orthographic projection of the corresponding first pixel aperture onto the base substrate 40.

Exemplarily, an overlapping area of the orthographic projection of the second lens 32 onto the base substrate 40 and the orthographic projection of the corresponding second pixel aperture onto the base substrate 40 is greater than or equal to 80% S, where S is an area of the orthographic projection of the corresponding second pixel aperture onto the base substrate 40.

Exemplarily, the light gathering ability of the first lens 31 is less than the light gathering ability of the second lens 32. The gathering effect of the first lens 31 on light emitted by the corresponding first sub-pixel is less than the gathering effect of the second lens 32 on light emitted by the corresponding second sub-pixel. That is, the brightness enhancement ability of the first lens 31 on the light emitted by the corresponding first sub-pixel is less than the brightness enhancement ability of the second lens 32 on the light emitted by the corresponding second sub-pixel.

According to the specific structure of the display panel, it can be seen that in the display panel provided by the embodiments of the present disclosure, the display panel includes a first display region 10 and a second display region 20. Among sub-pixels of the same color, the first pixel aperture located in the first display region 10 is greater than the second pixel aperture located in the second display region 20. The light gathering ability of the first lens 31 corresponding to the first sub-pixel in the lens layer is set to be less than the light gathering ability of the second lens 32 corresponding to the second sub-pixel in the lens layer, so that the brightness difference caused by the uneven apertures can be compensated, thereby effectively improving the brightness uniformity of the first display region 10 and the second display region 20.

More specifically, for example, the first sub-pixel includes the first red sub-pixel R1, and the second sub-pixel includes the second red sub-pixel R2. A first pixel aperture R1-K of the first red sub-pixel R1 is greater than a second pixel aperture R2-K of the second red sub-pixel R2. Before passing through the lens layer, the light emitting brightness of the first red sub-pixel R1 is greater than the light emitting brightness of the second red sub-pixel R2. The light gathering ability of the first lens 31 corresponding to the first red sub-pixel R1 is set to be less than the light gathering ability of the second lens 32 corresponding to the second red sub-pixel R2, so that the light emitting brightness difference of the first red sub-pixel R1 and the second red sub-pixel R2 is effectively compensated, and then the brightness of the red light emitted by the first lens 31 and the brightness of the red light emitted by the second lens 32 have good uniformity.

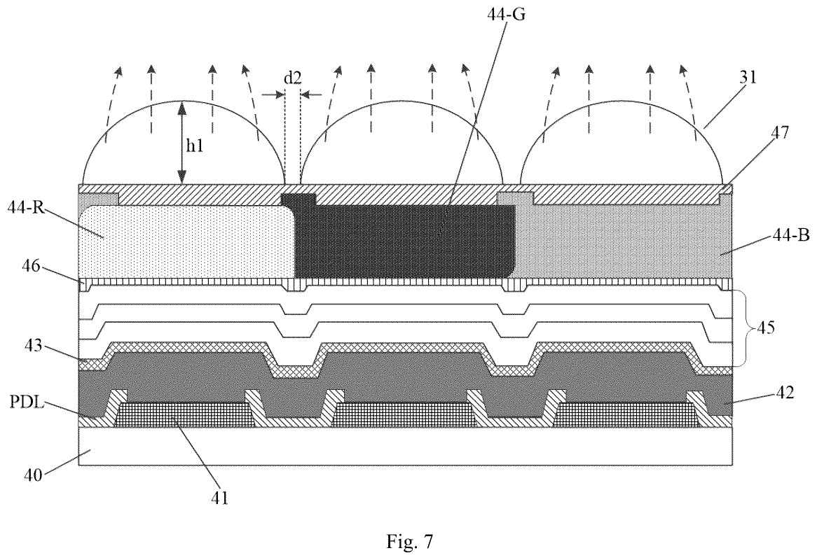

As shown in FIG. 5, FIG. 7 and FIG. 8, in some embodiments, an arch height of the first lens 31 is less than an arch height of the second lens 32.

It is to be noted that the arch height of the lens is the maximum height of the lens in a direction perpendicular to the base substrate 40.

Exemplarily, when the arch height of the lens is 2.3 μm, the corresponding gain is 1.9 times; and the corresponding gain is 1.3 times when the arch height of the lens is 1.2 μm.

In the display panel provided by the foregoing embodiments, the brightness gain can be improved by 1.2-1.9 times by arranging the lens.

In the display panel provided by the foregoing embodiments, the arch height of the first lens 31 is set to be less than the arch height of the second lens 32, so that the light gathering gain of the first lens 31 is less than the light gathering gain of the second lens 32. The first lens 31 is arranged at the light emitting side of the first sub-pixel and the second lens 32 is arranged at the light emitting side of the second sub-pixel, so that the brightness difference caused by the first pixel aperture being greater than the second pixel aperture can be compensated, thereby effectively improving the brightness uniformity of the first display region 10 and the second display region 20.

As shown in FIG. 5, FIG. 7 and FIG. 8, in some embodiments, the arch height h1 of the first lens satisfies: 1.2 μm≤h1≤2.3 μm.

Exemplarily, the arch height h1 of the first lens 31 may be 1.2 μm, 1.4 μm, 1.6 μm, 1.8 μm, 2.0 μm, and 2.2 μm, but is not limited thereto.

It is to be noted that the arch height h2 of the second lens 32 may also be set within the above range. Exemplarily, the arch height h2 of the second lens 32 may be 1.3 μm, 1.5 μm, 1.7 μm, 1.9 μm, 2.1 μm, and 2.3 μm, but is not limited thereto.

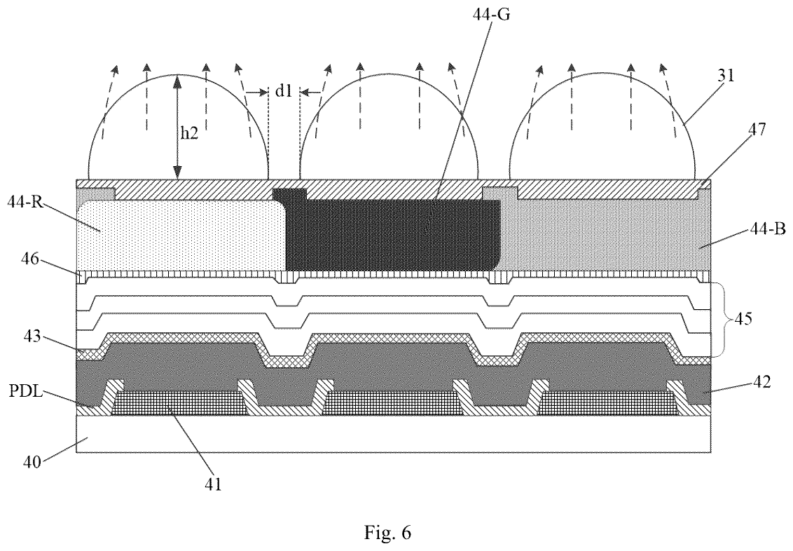

As shown in FIG. 5, FIG. 6 and FIG. 8, in some embodiments, a distance d1 between orthographic projections of the adjacent first lenses onto the base substrate and a distance d2 between orthographic projections of the adjacent second lenses onto the base substrate satisfy: d1>d2.

Exemplarily, an area of an orthographic projection of the first lens 31 onto the base substrate 40 is less than an area of an orthographic projection of the second lens 32 onto the base substrate 40.

Exemplarily, an overlapping area between an orthographic projection of the first lens 31 onto the base substrate 40 and an orthographic projection of the corresponding first pixel aperture onto the base substrate 40, is less than an overlapping area between an orthographic projection of the second lens 32 onto the base substrate 40 and an orthographic projection of the corresponding second pixel aperture onto the base substrate 40.

Exemplarily, a minimum distance between orthographic projections of two adjacent first lenses 31 onto the base substrate 40, is greater than a minimum distance between orthographic projections of two adjacent second lenses 32 onto the base substrate 40.

In the display panel provided by the foregoing embodiments, the distance d1 between the orthographic projections of the adjacent first lenses 31 onto the base substrate 40 is set to be greater than the distance d2 between the orthographic projections of the adjacent second lenses 32 onto the base substrate 40, so that the overlapping area between the orthographic projection of the first lens 31 onto the base substrate 40 and the orthographic projection of the corresponding first pixel aperture onto the base substrate 40 is less than the overlapping area between the orthographic projection of the second lens 32 onto the base substrate 40 and the orthographic projection of the corresponding second pixel aperture onto the base substrate 40, thereby reducing the effective light gathering region of the first lens 31. Then, the first lens 31 is arranged at the light emitting side of the first sub-pixel, and the second lens 32 is arranged at the light emitting side of the second sub-pixel, so that the brightness difference caused by the first pixel aperture being greater than the second pixel aperture can be compensated, thereby effectively improving the brightness uniformity of the first display region 10 and the second display region 20.

As shown in FIG. 5, FIG. 6 and FIG. 8, in some embodiments, the distance d1 between orthographic projections of the adjacent first lenses onto the base substrate satisfies: 0.3 μm≤d1≤1 μm.

Exemplarily, the distance d1 between the orthographic projections of the adjacent first lenses 31 onto the base substrate 40 may be 0.3 μm, 0.5 μm, 0.7 μm, 0.9 μm, and 1 μm, but is not limited thereto.

It is to be noted that the distance d2 between the orthographic projections of the adjacent second lenses 32 onto the base substrate 40 may also be set within the above ranges. Exemplarily, the distance d2 between the orthographic projections of the adjacent second lenses 32 onto the base substrate 40 may be 0.2 μm, 0.4 μm, 0.6 μm, 0.8 μm, and 0.9 μm, but is not limited thereto.

As shown in FIG. 5, FIG. 6, FIG. 7 and FIG. 8, in some embodiments, the arch height h1 of the first lens 31 is less than the arch height h2 of the second lens 32; and/or, the distance d1 between orthographic projections of the adjacent first lenses 31 onto the base substrate 40 and the distance d2 between orthographic projections of the adjacent second lenses 32 onto the base substrate 40 satisfy: d1>d2.

In the display substrate provided by the foregoing embodiments, it is possible to adjust only the arch height of the lens, adjust only the distance between adjacent lenses, or adjust both simultaneously. In the case that only the arch height of the first lens 31 is set to be less than the arch height of the second lens 32, it is set that d1=d2. When setting d1>d2, h1=h2 is set.

As shown in FIG. 3, in some embodiments, the orthographic projection of the first lens 31 onto the base substrate 40 is surrounded by the orthographic projection of the corresponding first pixel aperture onto the base substrate 40.

The foregoing arrangement reduces the effective light gathering region of the first lens 31. Then, the first lens 31 is arranged at the light emitting side of the first sub-pixel, and the second lens 32 is arranged at the light emitting side of the second sub-pixel, so that the brightness difference caused by the first pixel aperture being greater than the second pixel aperture can be compensated, thereby effectively improving the brightness uniformity of the first display region 10 and the second display region 20.

As shown in FIG. 3, in some embodiments, the orthographic projection of the second lens 32 onto the base substrate 40 surrounds at least part of a boundary of the orthographic projection of the corresponding second pixel aperture onto the base substrate 40.

In some embodiments, the orthographic projection of the second lens 32 onto the base substrate 40 surrounds the orthographic projection of the corresponding second pixel aperture onto the base substrate 40.

The foregoing arrangement reduces the effective light gathering region of the first lens 31 and increases the effective light gathering region of the second lens 32. Then, the first lens 31 is arranged at the light emitting side of the first sub-pixel, and the second lens 32 is arranged at the light emitting side of the second sub-pixel, so that the brightness difference caused by the first pixel aperture being greater than the second pixel aperture can be compensated, thereby effectively improving the brightness uniformity of the first display region 10 and the second display region 20.

In some embodiments, a material of the first lens is different from a material of the second lens, and a refractive index of the material of the first lens is less than a refractive index of the material of the second lens.

Exemplarily, the first lens 31 and the second lens 32 may be made of an inorganic material or an organic material.

The refractive index of the material of the first lens 31 is set to be less than the refractive index of the material of the second lens 32, so that the light gathering ability of the first lens 31 is less than the light gathering ability of the second lens 32. Then, the first lens 31 is arranged at the light emitting side of the first sub-pixel, and the second lens 32 is arranged at the light emitting side of the second sub-pixel, so that the brightness difference caused by the uneven opening can be compensated, thereby effectively improving the brightness uniformity of the first display region 10 and the second display region 20.

In some embodiments, the second display region 20 includes a sub-display region and the sub-display region is adjacent to the first display region 10. In the sub-display region, the light gathering ability of the second lens 32 corresponding to the second sub-pixel is gradually reduced in a direction close to the first display region 10.

The sub-pixel region includes at least two rows of second sub-pixels, or the sub-pixel region includes at least two columns of second sub-pixels.

Exemplarily, in the sub-display region, an arch height of the second lens 32 corresponding to the second sub-pixel is gradually reduced in the direction close to the first display region 10.

Exemplarily, a distance between orthographic projections of the adjacent second lenses 32 onto the base substrate 40 is d2; in the sub-display region, d2 gradually increases in the direction close to the first display region 10.

In the display substrate provided by the foregoing embodiments, in the sub-display region, the light gathering ability of the second lens 32 corresponding to the second sub-pixel is set to be gradually reduced in a direction close to the first display region, so that the boundary between the first display region 10 and the second display region 20 can be better fuzzified, thereby facilitating the compensation of the brightness uniformity of the first display region 10 and the second display region 20.

In some embodiments, the plurality of first sub-pixels include a plurality of first blue sub-pixels B1, a plurality of first green sub-pixels G1 and a plurality of first red sub-pixels R1;
the light gathering ability of the first lens 31 corresponding to the first blue sub-pixel B1 is greater than the light gathering ability of the first lens 31 corresponding to the first green sub-pixel G1; and/or,
the light gathering ability of the first lens 31 corresponding to the first blue sub-pixel B1 is greater than the light gathering ability of the first lens 31 corresponding to the first red sub-pixel R1.

Due to the fact that the light emitting brightness of the first blue sub-pixel B1 is weaker than the light emitting brightness of the sub-pixels of other colors in the display panel, the foregoing arrangement is beneficial to improving the light emitting brightness of the first blue sub-pixel B1, thereby improving the display quality of the display panel.

In some embodiments, the plurality of second sub-pixels include a plurality of second blue sub-pixels B2, a plurality of second green sub-pixels G2 and a plurality of second red sub-pixels R2;
the light gathering ability of the second lens 32 corresponding to the second blue sub-pixel B2 is greater than the light gathering ability of the second lens 32 corresponding to the second green sub-pixel G2; and/or,
the light gathering ability of the second lens 32 corresponding to the second blue sub-pixel B2 is greater than the light gathering ability of the second lens 32 corresponding to the second red sub-pixel R2.

Due to the fact that the light emitting brightness of the second blue sub-pixel B2 is weaker than the light emitting brightness of the sub-pixels of other colors in the display panel, the foregoing arrangement is beneficial to improving the light emitting brightness of the second blue sub-pixel B2, thereby improving the display quality of the display panel.

In addition, in the display panel provided by the foregoing embodiments, by improving the light emitting brightness of the first blue sub-pixel B1 and the second blue sub-pixel B2, the display effect of the cold tone of the display panel can be achieved, thereby better satisfying user requirements.

In some embodiments, the plurality of first sub-pixels include a plurality of first blue sub-pixels B1, a plurality of first green sub-pixels G1 and a plurality of first red sub-pixels R1;
the light gathering ability of the first lens 31 corresponding to the first red sub-pixel R1 is greater than the light gathering ability of the first lens 31 corresponding to the first green sub-pixel G1; and/or,
the light gathering ability of the first lens 31 corresponding to the first red sub-pixel R1 is greater than the light gathering ability of the first lens 31 corresponding to the first blue sub-pixel B1.

In some embodiments, the plurality of second sub-pixels include a plurality of second blue sub-pixels B2, a plurality of second green sub-pixels G2 and a plurality of second red sub-pixels R2;
the light gathering ability of the second lens 32 corresponding to the second red sub-pixel R2 is greater than the light gathering ability of the second lens 32 corresponding to the second green sub-pixel G2; and/or,
the light gathering ability of the second lens 32 corresponding to the second red sub-pixel R2 is greater than the light gathering ability of the second lens 32 corresponding to the second blue sub-pixel B2.

In the display substrate provided by the foregoing embodiments, the light gathering ability of the second lens 32 corresponding to the first red sub-pixel R1 and the second red sub-pixel R2 is set to be greater than the light gathering ability of the lenses corresponding to the sub-pixels of other colors, so that the light emitting brightness of the first red sub-pixel R1 and the light emitting brightness of the second red sub-pixel R2 can be improved, and the display effect of the warm tone of the display panel can be achieved, thereby better satisfying user requirements.

As shown in FIG. 5 to FIG. 8, in some embodiments, each of the first sub-pixel and the second sub-pixel includes: a sub-pixel driving circuit and a light-emitting element. The light-emitting element includes an anode pattern 41, a light-emitting functional layer 42, a cathode layer 43 and a color film layer, which are stacked sequentially in a direction away from the base substrate 40. The anode pattern 41 is coupled to the sub-pixel driving circuit. The display panel further includes: a pixel defining layer PDL. At least part of the pixel defining layer PDL is located between the anode pattern 41 and the light-emitting functional layer 42. The pixel defining layer includes a plurality of openings and the plurality of openings are used for defining the first pixel aperture and the second pixel aperture.

Exemplarily, the light-emitting functional layer 42 may include a hole injection layer, a hole transport layer, an organic light-emitting material layer, an electron transport layer, and an electron injection layer stacked on the base substrate 40, but is not limited thereto. Exemplarily, the organic light-emitting material layer emits white light. The white light passes through the corresponding color film layer, and the white light is changed into the corresponding color light to finally emit out of the display panel, thereby achieving the display function of the display panel.

Exemplarily, the sub-pixel includes a sub-pixel driving circuit and a light-emitting element. The sub-pixel driving circuit is coupled to the anode pattern 41 to provide a driving signal for the light-emitting element. The light-emitting functional layer 42 emits light under the action of an electric field between the anode pattern 41 and the cathode layer 43, and the light passes through the color film layer and then is emitted to the corresponding lens.

Exemplarily, the display panel further includes a pixel defining layer PDL and the pixel defining layer PDL undergoes a photolithography process implemented by a fine exposure machine.

More specifically, a pixel defining film is formed by using a pixel defining material. The fine exposure machine is used to perform multiple exposures on regions of the pixel defining thin film. The pixel defining layer PDL located in the first display region 10 is repeatedly exposed. The pixel defining layer PDL is formed by the pixel defining film after the photolithography process, and the pixel defining layer PDL includes the plurality of openings distributed in an array.

Exemplarily, the color film layer included in the red sub-pixels is the red color film layer 44-R, the color film layer included in the green sub-pixels is the green color film layer 44-G, and the color film layer included in the blue sub-pixels is the blue color film layer 44-B.

Exemplarily, the red color film layer 44-R, the blue color film layer 44-B, and the green color film layer 44-G are respectively formed by evaporation by using an evaporation process, and the color film layer evaporated after evaporation covers the boundary of the color film layer formed by evaporation.

In some embodiments, the display substrate further includes: an encapsulation layer 45, a planarization layer 46, and a cover plate 47. The encapsulation layer 45 is located between the cathode layer 43 and the color film layer. The planarization layer 46 is located between the encapsulation layer 45 and the color film layer. The cover plate 47 is located between the color film layer and the lens layer.

Exemplarily, the encapsulation layer 45 includes at least one inorganic encapsulation layer 45. Exemplarily, the encapsulation layer 45 includes three layers of stacked inorganic encapsulation layers 45, but is not limited thereto.

Exemplarily, the planarization layer 46 is made of an organic material, but is not limited thereto.

Embodiments of the present disclosure further provide a display device, including the display panel provided by the foregoing embodiments.

It is to be noted that the display device can be: a TV, a monitor, a digital photo frame, a mobile phone, a tablet computer or any other product or component with a display function. The display device further includes a flexible circuit board, a printed circuit board and a backplane, etc. The display device may also include a near-eye display device, an AR/VR device, etc.

In the display panel provided in the foregoing embodiments, the display panel includes the first display region 10 and the second display region 20. Among sub-pixels of the same color, the first pixel aperture of the first sub-pixel located in the first display region 10 is greater than the second pixel aperture of the second sub-pixel located in the second display region 20. The light gathering ability of the first lens 31 corresponding to the first sub-pixel in the lens layer is set to be less than the light gathering ability of the second lens 32 corresponding to the second sub-pixel in the lens layer, so that the brightness difference caused by the uneven opening can be compensated, thereby effectively improving the brightness uniformity of the first display region 10 and the second display region 20. More specifically, for example, the first sub-pixel includes the first red sub-pixel R1, and the second sub-pixel includes the second red sub-pixel R2. A first pixel aperture R1-K of the first red sub-pixel R1 is greater than a second pixel aperture R2-K of the second red sub-pixel R2. Before passing through the lens layer, the light emitting brightness of the first red sub-pixel R1 is greater than the light emitting brightness of the second red sub-pixel R2. The light gathering ability of the first lens 31 corresponding to the first red sub-pixel R1 is set to be less than the light gathering ability of the second lens 32 corresponding to the second red sub-pixel R2, so that the light emitting brightness difference of the first red sub-pixel R1 and the second red sub-pixel R2 is effectively compensated, and then the brightness of the red light emitted by the first lens 31 and the brightness of the red light emitted by the second lens 32 have good uniformity.

The display devices provided by embodiments of the present disclosure also have the foregoing beneficial effects when including the foregoing display panel. Details are not further described herein.

It is to be noted that “the same film layer” in an embodiment of the present disclosure may refer to a film layer located on the same structural layer. Alternatively, for example, the film layer at the same level may be a film layer formed to have a particular pattern by using the same film-forming process. The film layer may then be patterned by one patterning process using the same mask to form the desired layer structure. Depending on different particular patterns, the one patterning process may include multiple exposing, developing, or etching processes. Further, as an example, a particular pattern in the formed layer structure may be continuous or discontinuous. As other example, these particular patterns may be at different heights or have different thicknesses.

In the method embodiments of the invention, the sequential number of each step is not used to limit the order of the steps. Instead, the order of the steps may be changed by those skilled in the art without any inventive effort and is thus under the protection of the invention.

It is to be noted that the various embodiments in the present description are described in a progressive manner, and the various embodiments may refer to each other for the same or similar parts, and each embodiment focuses on differences from other embodiments. Especially, for the method embodiment, since it is basically similar to the product embodiment, the description is relatively simple, and the relevant parts can be referred to the description of the product embodiment.

Unless otherwise defined, technical terms or scientific terms used in the present disclosure shall have the common meanings understood by those with ordinary skills in the field to which the present disclosure belongs. “First”, “second” and similar words used in the present disclosure do not indicate any order, quantity, or importance, but are only used to distinguish different components. “Including” or “containing” and other similar words mean that the element or item before the word encompasses the element or item and their equivalents listed after the word, but does not exclude other elements or items. Similar words such as “coupled” or “connected” are not limited to physical or mechanical connections, but may include electrical connections, whether direct or indirect. “Up”, “down”, “left”, “right”, etc. are only used to indicate a relative position relationship. When an absolute position of a described object changes, the relative position relationship may also change accordingly.

It is to be appreciated that, in the case that such an element as layer, film, region or substrate is arranged “on” or “under” another element, it may be directly arranged “on” or “under” the other element, or an intermediate element may be arranged therebetween.

In descriptions of the implementation modes, the specific features, structures, materials, or characteristics described may be combined in any suitable manner in any one or more embodiments or examples.

The foregoing are only specific embodiments of the present disclosure, but the protection scope of the present disclosure is not limited thereto. In the technical scope disclosed by the present disclosure, changes or substitutions easily thought by any skilled in the art are all covered in the protection scope of the present disclosure. Therefore, the protection scope of the present disclosure should be the protection scope of the claims.

1. A display panel, comprising:
a base substrate; and
a plurality of sub-pixels on the base substrate;
wherein the base substrate comprises a first display region and a second display region; the plurality of sub-pixels comprise a plurality of first sub-pixels and a plurality of second sub-pixels; the plurality of first sub-pixels are in the first display region; the plurality of second sub-pixels are in the second display region; among sub-pixels of an identical color, a first pixel aperture of the first sub-pixels is greater than a second pixel aperture of the second sub-pixels;
wherein the display panel further comprises:
a lens layer at a side of the plurality of sub-pixels facing away from the base substrate; wherein the lens layer comprises a plurality of first lenses and a plurality of second lenses; an orthographic projection of the first lens onto the base substrate at least partially overlaps with an orthographic projection of the corresponding first pixel aperture onto the base substrate; an orthographic projection of the second lens onto the base substrate at least partially overlaps with an orthographic projection of the corresponding second pixel aperture onto the base substrate;
a light gathering ability of the first lens is less than a light gathering ability of the second lens.

2. The display panel according to claim 1, wherein an arch height of the first lens is less than an arch height of the second lens.

3. The display panel according to claim 2, wherein the arch height h1 of the first lens satisfies: 1.2 μm≤h1≤2.3 μm.

4. The display panel according to claim 1, wherein a distance d1 between orthographic projections of adjacent ones of the plurality of first lenses onto the base substrate and a distance d2 between orthographic projections of adjacent ones of the plurality of second lenses onto the base substrate satisfy: d1>d2.

5. The display panel according to claim 4, wherein d1 satisfies: 0.3 μm≤d1≤1 μm.

6. The display panel according to claim 1, wherein the orthographic projection of the first lens onto the base substrate is surrounded by the orthographic projection of the corresponding first pixel aperture onto the base substrate.

7. The display panel according to claim 1, wherein the orthographic projection of the second lens onto the base substrate surrounds at least part of a boundary of the orthographic projection of the corresponding second pixel aperture onto the base substrate.

8. The display panel according to claim 7, wherein the orthographic projection of the second lens onto the base substrate surrounds the orthographic projection of the corresponding second pixel aperture onto the base substrate.

9. The display panel according to claim 1, wherein a material of the first lens is different from a material of the second lens, and a refractive index of the material of the first lens is less than a refractive index of the material of the second lens.

10. The display panel according to claim 1, wherein the second display region comprises a sub-display region and the sub-display region is adjacent to the first display region; in the sub-display region, the light gathering ability of the second lens corresponding to the second sub-pixel is gradually reduced in a direction close to the first display region.

11. The display panel according to claim 10, wherein in the sub-display region, an arch height of the second lens corresponding to the second sub-pixel is gradually reduced in the direction close to the first display region.

12. The display panel according to claim 10, wherein a distance between orthographic projections of adjacent ones of the plurality of second lenses onto the base substrate is d2; in the sub-display region, d2 gradually increases in the direction close to the first display region.

13. The display panel according to claim 1, wherein the plurality of first sub-pixels comprise a plurality of first blue sub-pixels, a plurality of first green sub-pixels and a plurality of first red sub-pixels;
the light gathering ability of the first lens corresponding to the first blue sub-pixel is greater than the light gathering ability of the first lens corresponding to the first green sub-pixel; and/or,
the light gathering ability of the first lens corresponding to the first blue sub-pixel is greater than the light gathering ability of the first lens corresponding to the first red sub-pixel.

14. The display panel according to claim 1, wherein the plurality of second sub-pixels comprise a plurality of second blue sub-pixels, a plurality of second green sub-pixels and a plurality of second red sub-pixels;
the light gathering ability of the second lens corresponding to the second blue sub-pixel is greater than the light gathering ability of the second lens corresponding to the second green sub-pixel; and/or,
the light gathering ability of the second lens corresponding to the second blue sub-pixel is greater than the light gathering ability of the second lens corresponding to the second red sub-pixel.

15. The display panel according to claim 1, wherein the plurality of first sub-pixels comprise a plurality of first blue sub-pixels, a plurality of first green sub-pixels and a plurality of first red sub-pixels;
the light gathering ability of the first lens corresponding to the first red sub-pixel is greater than the light gathering ability of the first lens corresponding to the first green sub-pixel; and/or,
the light gathering ability of the first lens corresponding to the first red sub-pixel is greater than the light gathering ability of the first lens corresponding to the first blue sub-pixel.

16. The display panel according to claim 1, wherein the plurality of second sub-pixels comprise a plurality of second blue sub-pixels, a plurality of second green sub-pixels and a plurality of second red sub-pixels;
the light gathering ability of the second lens corresponding to the second red sub-pixel is greater than the light gathering ability of the second lens corresponding to the second green sub-pixel; and/or,
the light gathering ability of the second lens corresponding to the second red sub-pixel is greater than the light gathering ability of the second lens corresponding to the second blue sub-pixel.

17. The display panel according to claim 1, wherein each of the first sub-pixel and the second sub-pixel comprises: a sub-pixel driving circuit and a light-emitting element; the light-emitting element comprises an anode pattern, a light-emitting functional layer, a cathode layer and a color film layer which are sequentially stacked in a direction away from the base substrate; and the anode pattern is coupled to the sub-pixel driving circuit;
the display panel further comprises a pixel defining layer; at least part of the pixel defining layer is between the anode pattern and the light-emitting functional layer; the pixel defining layer comprises a plurality of openings and the plurality of openings define the first pixel aperture and the second pixel aperture.

18. A display device, comprising a display panel:
wherein the display panel comprises:
a base substrate; and
a plurality of sub-pixels on the base substrate;
wherein the base substrate comprises a first display region and a second display region; the plurality of sub-pixels comprise a plurality of first sub-pixels and a plurality of second sub-pixels; the plurality of first sub-pixels are in the first display region; the plurality of second sub-pixels are in the second display region; among sub-pixels of an identical color, a first pixel aperture of the first sub-pixels is greater than a second pixel aperture of the second sub-pixels;
wherein the display panel further comprises:
a lens layer at a side of the plurality of sub-pixels facing away from the base substrate; wherein the lens layer comprises a plurality of first lenses and a plurality of second lenses; an orthographic projection of the first lens onto the base substrate at least partially overlaps with an orthographic projection of the corresponding first pixel aperture onto the base substrate; an orthographic projection of the second lens onto the base substrate at least partially overlaps with an orthographic projection of the corresponding second pixel aperture onto the base substrate;
a light gathering ability of the first lens is less than a light gathering ability of the second lens.

19. The display device according to claim 18, wherein an arch height of the first lens is less than an arch height of the second lens.

20. The display device according to claim 19, wherein the arch height h1 of the first lens satisfies: 1.2 μm≤h1≤2.3 μm.
